(19) United States
(12) Patent Application Publication
(10) Pub. No.: US 2007/0228879 A1
(43) Pub. Date: Oct. 4, 2007

(54) Cutting device, processing apparatus, molding die, optical element and cutting method

(75) Inventors: Toshiyuki Imai, Tokyo (JP); Isao Takano, Tokyo (JP)

Correspondence Address: COHEN, PONTANI, LIEBERMAN & PAVANE, 551 FIFTH AVENUE, SUITE 1210, NEW YORK, NY, 10176, US

(73) Assignee: Konica Minolta Opto, Inc., Tokyo (JP)

(21) Appl. No.: 11/729,042

(22) Filed: Mar. 28, 2007

(30) Foreign Application Priority Data
Mar. 30, 2006 (JP) JP2006-095793

(51) Int. Cl. H01L 41/00

(52) U.S. Cl. 310/323.01

(57) ABSTRACT

In a cutting tool, a shank is a support member made of ceramics and although it is light, it is hardly bent. Further, a processing tip made of a diamond having a cutting edge and is fixed to the tip portion of the shank by an active metal method or brazing. The shank is fixed so as to be pressed to the bottom surface of a slit-shaped groove formed in a fixing portion by a fixing screw and a washer. In this case, the washer is a ring-shaped member transforming as a cushioning member and prevents the fastening stress by the fixing screw from locally concentrating.

This application is based on Japanese Patent Application No. 2006-095793 filed on Mar. 30, 2006 in Japanese Patent Office, the entire content of which is hereby incorporated by reference.

### BACKGROUND OF THE INVENTION

The present invention relates to a cutting device and a processing device used favorably in the case of forming a molding die for an optical element and others, and a molding die and an optical element produced by using the aforesaid devices.

There is available a technology to cut materials such as carbide and glass which are hard-to-cut materials by vibrating a tip of a cutting tool such as a diamond tool, which is called vibration cutting. In this technology, minute cutting-in is conducted at high speed by a cutting edge of a cutting tool through vibration, and chips generated in this time are scraped out by the cutting edge through vibration, resulting in realization of cutting processes which cause less stress for a cutting tool and a material to be cut (for example, see Patent Documents 1, 2, 3 and 4). Owing to this process of vibration cutting, a critical depth of cut needed for an ordinary cutting of ductile mode is improved to be several times as large as its normal depth, thus, the hard-to-cut materials can be subjected to cutting process at high efficiency.

In such process of vibration cutting of this kind, high speed vibration of 20 kHz or more is usually used, because for improving the efficiency of processing, when a vibration frequency is enhanced, the aforesaid effects are increased and a feed rate for the tool is also enhanced in proportion substantially to the frequency. There is also an advantage that an oscillator or a vibration body excited by the oscillator does not cause an offensive noise, because the aforesaid frequency is beyond a human audible range.

As a method to generate high speed vibration on a cutting edge of a cutting tool, a method has been put to practical use wherein a holding member that holds a tool is excited with a piezoelectric element or a super-magnetostrictor, to vibrate stably as a standing wave, by resonating this holding member with bending vibration and axial vibration (axial direction vibration).

In the aforementioned method, the cutting tool has a tip equipped with a cutting edge made of a diamond and the tip is brazed to a shank made of high-speed steel or cemented carbide. Such a cutting tool is fixed to a support body as a vibration body via the shank by fastening members such as bolts and nuts.

However, the cutting tool aforementioned is heavy because the shank is made of high-speed steel or cemented carbide and there are possibilities that although vibration is given, the amplitude thereof may be attenuated.

Here, although it may be considered to form the shank of the cutting tool of light and strong ceramics, ceramics have a low fracture toughness value, thus if it is intended to screw the shank with sufficient strength, there are possibilities that the shank may be damaged. Particularly, if the contact of a screw on the shank is not uniform, stress is concentrated at one location, thus there are possibilities of damage of the shank.

Patent Document 1: Unexampled Japanese Patent Application Publication No. 2000-52101

Patent Document 2: Unexampled Japanese Patent Application Publication No. 2000-218401

Patent Document 3: Unexampled Japanese Patent Application Publication No. Hei 9-309001

Patent Document 4: Unexampled Japanese Patent Application Publication No. 2002-126901

### SUMMARY

Therefore, the present invention is intended to provide a cutting device for surely fixing a shank while reducing attenuation of the amplitude and preventing the shank from being damaged and a processing device with the cutting device incorporated.

Further, the present invention is intended to provide a molding die and an optical element prepared with high precision using the above cutting device.

To solve the aforementioned problems, the cutting device relating to the present invention includes (a) a cutting tool for vibration cutting having a tip with a cutting edge and a shank made of ceramics for holding the tip, (b) a support body for supporting the shank of the cutting tool and transferring vibration to the cutting tool, (c) a fastening member for fastening and fixing the cutting tool to the support body, and (d) a cushioning member made of a material whose hardness is lower than that of the material of the shank body and that of the material of the fastening member body between the shank and the head portion of the fastening member.

The processing device relating to the present invention includes (a) the aforementioned cutting device and (b) a drive device for shifting the cutting device while operating the cutting device. In this processing device, the cutting device described above is shifted by the drive device, so that highly precise processing can be realized by the cutting device having the cutting tool which is light and is fixed surely by sufficient strength.

The molding die relating to the present invention has a transfer optical surface for forming an optical surface of the optical element, which is processed and created using the aforementioned cutting device. In this case, molding dies having a concavity and other various types of transfer optical surfaces can be processed with high precision.

The optical element relating to the present invention is processed and created using the aforementioned cutting device. In this case, a highly precise optical element having a convexity and other various types of optical surfaces can be obtained directly.

The cutting method relating to the present invention is a cutting method for giving vibration to the aforementioned cutting device for cutting.

### BRIEF DESCRIPTION OF THE DRAWINGS

FIGS. 1(a), 1(b), and 1(c) are a plan view, a side view, and an end face view of the vibration cutting unit of the first embodiment.

FIG. 2 is a plan view of the vibration body assembly.

FIGS. 3(a) and 3(b) are a side view and an end face view for describing the shape of the flange portion.

FIGS. 4(a) and 4(b) are an enlarged side view and an enlarged cross sectional view for describing the structure and fixing method of the cutting tool.

FIG. 5 is an enlarged cross sectional view for describing a variation example of the fixing method for the cutting tool shown in FIG. 4.

FIG. 6 is an enlarged cross sectional view for describing a variation example of the fixing method for the cutting tool shown in FIG. 4.

FIG. 7 is an enlarged cross sectional view for describing a variation example of the fixing method for the cutting tool shown in FIG. 4.

FIG. 8 is an enlarged cross sectional view for describing a variation example of the fixing method for the cutting tool shown in FIG. 4.

FIG. 9 is an enlarged cross sectional view for describing a variation example of the fixing method for the cutting tool shown in FIG. 4.

FIG. 10 is a block diagram for describing the processing device of the second embodiment.

FIG. 11 is an enlarged plan view for describing the processing of a workpiece using the processing device shown in FIG. 10.

FIGS. 12(a) and 12(b) are side cross sectional views of the molding die relating to the third embodiment.

FIG. 13 is a side cross sectional view of the lens formed with the molding die shown in FIG. 12.

### DETAILED DESCRIPTION OF THE PREFERRED EMBODIMENT

In the aforementioned cutting device, the cushioning member arranged between the pressed portion of the shank and the pressing portion of the fastening member is formed by including a material having hardness smaller than that of the body material of the shank made of ceramics and that of the body material of the fastening member, so that the shank made of ceramics having a comparatively low fracture toughness value can be fastened by the fastening member at a predetermined position of the support body with sufficient strength and surely fixed. In this case, the cushioning material is transformed and can prevent the shank from being applied with local stress, so that the possibility of cracking of the shank can be reduced and the life span of the cutting tool can be lengthened. Namely, along fine irregularities on the surfaces of the pressing portion of the fastening member and the pressed portion of the shank, the cushioning member entering therebetween is transformed and the contact area between the fastening member and the cushioning member or between the shank and the cushioning member increases and the cutting tool can be fixed strongly.

The concrete embodiment of the present invention is that in the cutting device aforementioned, the fastening member is a threaded member in a male screw shape and the cushioning member is a ring-shaped member in a washer shape (plate-shape). In this case, a male screw can be screwed into the support body to fix the shank and between the bottom (the seat on the fastening side) of the head portion of the threaded member which is a pressing portion and the opening peripheral (the seat on the fastened side) provided on the shank which is a pressed portion, the cushioning member can be held easily.

Another embodiment of the present invention is that the cushioning member is formed beforehand in the shape corresponding to the shape of the pressing portion of the fastening member. In this case, the cushioning member is held between the pressed portion and the pressing portion without transforming greatly.

Still another embodiment of the present invention is that the cushioning member can be formed in the shape corresponding to the shape of the pressing portion of the fastening member. In this case, the cushioning member is transformed and is held between the pressed portion and the pressing portion.

A further embodiment of the present invention is that the cushioning member has a surface made of a material including a soft metal. In this case, the cushioning member is transformed easily at low stress and is apt to be closely adhered to the pressed portion and pressing portion, so that the shank can be fixed strongly to the support body.

A still further embodiment of the present invention is that the hardness of the body material of the fastening member is lower than the hardness of the support body. In this case, the fastening member is relatively lower in hardness than the support body, and the support body is hardly spoiled, deformed, and damaged furthermore, so that while ensuring reuse of the fastening member to a certain extent, the life span of the support body can be lengthened furthermore.

Yet a further embodiment of the present invention is that the soft metal composing the cushioning member includes at least one element selected from the group of Al, Cu, Pb, Ti, Sn, Zn, Ag, Au, and Ni.

Yet a further embodiment of the present invention is that the cushioning member has Vickers hardness of HV200 or lower.

Yet a further embodiment of the present invention is that the cushioning member is a coating layer on the head portion of the fastening member or the shank.

Yet a further embodiment of the present invention is that the support body composes the vibration body for transferring the bending vibration and axial vibration to the cutting tool. In this case, the vibration body can give the bending vibration and axial vibration to the cutting tool and enables vibration cutting by variously vibrating the cutting tool.

Yet a further embodiment of the present invention is that the apparatus further has a vibration source for giving vibration to the vibration body, thereby vibrating the cutting tool via the vibration body. In this case, electric power is supplied to the vibration source, thus necessary vibration can be generated in the vibration body.

### First Embodiment

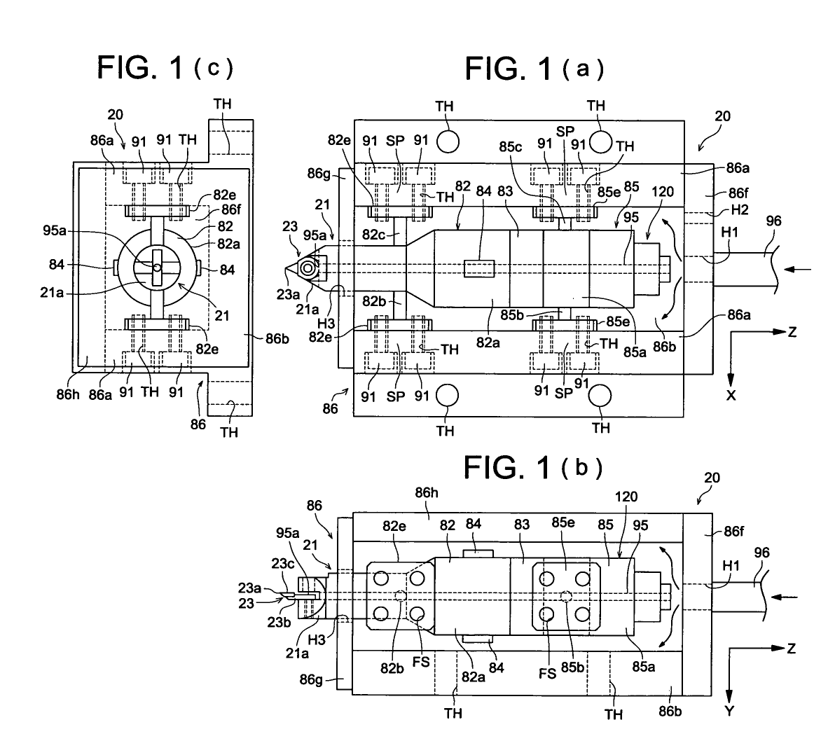

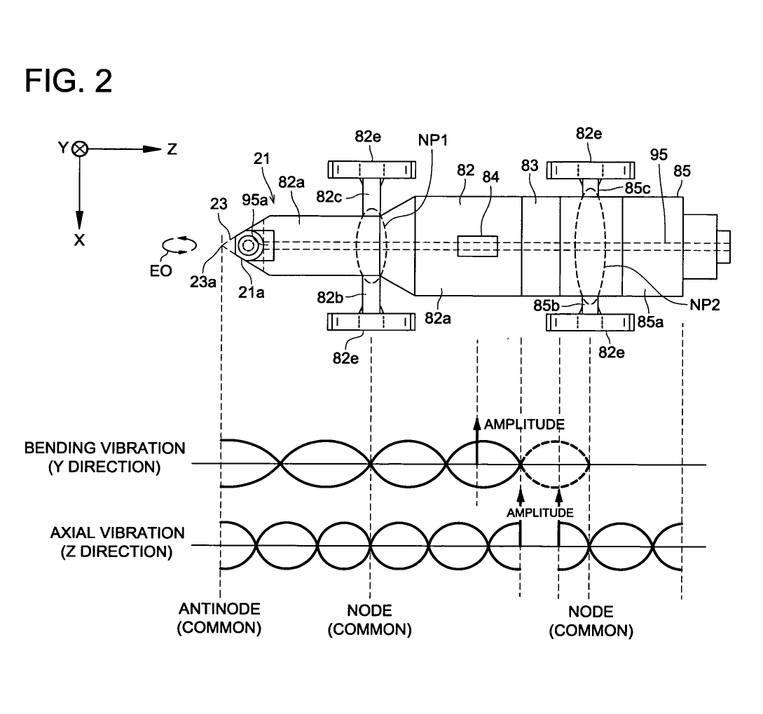

Hereinafter, the cutting device relating to the first embodiment of the present invention will be described with reference to the accompanying drawings. FIG. 1(a) is a plan view for describing the structure of the vibration cutting unit which is a cutting device for preparing the optical surface and transfer optical surface, and FIG. 1(b) is a side view of the vibration cutting unit, and FIG. 1(c) is an end face view of the vibration cutting unit. Further, FIG. 2 is a plan view of the vibration body assembly incorporated in the vibration cutting unit shown in FIG. 1.

As shown in FIGS. 1(a)-1(c), vibration cutting unit 20 is a tool for producing an optical surface of an optical element such as a lens or for producing a transfer optical surface of molding die for forming these optical surfaces by means of cutting processes. This vibration cutting unit 20 is provided with cutting tool 23, vibration body for cutting 82, axial direction oscillator 83, bending oscillator 84, counterbalance 85 and with case member 86. Meanwhile, a portion of one set including vibration body for cutting 82, axial direction oscillator 83, bending oscillator 84 and counterbalance 85 constitutes assembly of a vibration body 120, and this assembly of a vibration body 120 can be regarded as an integrated vibration body for cutting that is driven from the outside to vibrate under the desired state.

In this case, cutting tool 23 is embedded in to be fixed to fixing portion 21a provided on the tip of tool portion 21 representing the tip side of vibration body for cutting 82 of vibration cutting unit 20. The vibration body for cutting 82 or fixing portion 21a works as a support body for supporting cutting tool 23 while allowing the cutting tool 23 to vibrate. Cutting tool 23 whose tip 23a is serving as a cutting edge of diamond tip as described later, vibrates together with the tip of vibration body for cutting 82, namely, with fixing portion 21a as an open end of the vibration body for cutting 82 that is made to be in the state of resonance. In other words, the cutting tool 23 generates vibrations causing displacement in the Z direction, following vibrations in the axial direction of vibration body for cutting 82, and generates vibrations causing displacement in the Y direction, following the bending vibration of vibration body for cutting 82. As a result, tip 23a of cutting tool 23 is displaced at high speed, drawing elliptical orbit EO. Incidentally, in FIG. 1, elliptical orbit EO is drawn to spread slightly on XZ plane, for easy understanding. However, actual elliptical orbit EO drawn by the tip 23a exists on a plane that is in parallel with YZ plane.

The vibration body for cutting 82 is a vibration body for cutting formed integrally with a low linear expansion material in which an absolute value of the linear expansion coefficient is, for example, 2×10⁻⁶ or less, and specifically, Invar material, super Invar material and stainless Invar material are used favorably as a material. Incidentally, as a material for the vibration body for cutting 82, cemented carbide may also be used, although its linear expansion coefficient is relatively great to be about 6×10⁻⁶. Further, the vibration body for cutting 82 can be formed of iron, quenched steel, stainless steel, aluminium for a use that does not need processing precision.

The Invar material suitable for a material of the vibration body for cutting 82 is an alloy containing Fe and Ni, and it is an iron alloy containing Ni of 36 atomic percent whose coefficient of linear expansion at a room temperature is normally 1×10⁻⁶ or less. Its Young's modulus is as low as about a half of that of steel, and when this is used as a material of the vibration body for cutting 82, thermal expansion and contraction of the vibration body for cutting 82 are restricted, and temperature drift for the position of a cutting edge of cutting tool 23 held on the tip can be restricted.

Further, the super Invar material is an alloy containing at least Fe, Ni and Co, and it is an iron alloy containing Ni of 5 atomic percent or more and Co of 5 atomic percent or more, and its coefficient of linear expansion is normally about 0.4×10⁻⁶ at a room temperature, which means that the super Invar material is more resistant for thermal expansion and thermal contraction than the aforesaid Invar material. Its Young's modulus is as low as about a half of that of steel, and when this is used as a material of the vibration body for cutting 82, thermal expansion and thermal contraction of the vibration body for cutting 82 are restricted, and temperature drift for the position of a cutting edge of cutting tool 23 held on the tip can be restricted.

The stainless Invar material means all alloy materials wherein a main component with 50 atomic percent or more is Fe, and an incident material containing 5 atomic percent or more is at least one of Co, Cr and Ni. Therefore, in this case, Kovar material is also included in this stainless Invar material. The coefficient of linear expansion of the stainless Invar material is normally 1.3×10⁻⁶ or less at a room temperature. Incidentally, the coefficient of linear expansion of the Kovar material is normally 5×10⁻⁶ or less at a room temperature. Young's modulus of the stainless Invar material is as low as about a half of that of steel, and when this is used as a material of the vibration body for cutting 82, thermal expansion and contraction of the vibration body for cutting 82 are restricted, and temperature drift for the position of a cutting edge of cutting tool 23 held on the tip can be restricted. Further, the stainless Invar material is suitable as a material of the structure to hold and fix the cutting tool 23, because it has an excellent characteristic of being much higher than the Invar material in terms of resistance to moisture, and it does not gather rust even when it is exposed to a cooling liquid for processing.

The vibration body for cutting 82 is equipped with vibration body main part 82a that transmits a vibration to cutting tool 23, holding members 82b and 82c each supporting the vibration body main part 82a and flange portions 82e formed respectively on tip sides of holding members 82b and 82c. Among them, the vibration body main part 82a is a member whose axial direction is a Z axis direction. Though this vibration body main part 82a has an outer form of two-step cylindrical wherein diameters are different in the vicinity of node portion NP1 (see FIG. 2) in the case of the illustration, it can be replaced by one having a cross-sectional view, for example, of a square, a polygon or an ellipse, under the assumption that the expected state of vibration can be secured. Two holding members 82b and 82c extending to ±X directions respectively from a sidewall of the vibration body main part 82a support the vibration body main part 82a with node portion NP1 in a way not to disturb operations of the vibration body main part 82a. In the case of the illustration wherein each of the holding members 82b and 82c has a cylindrical external form, it is possible to replace them with those having an external form such as, for example, a square pole, other polyhedral poles or an elliptic cylinder. The root side of each of holding members 82b and 82c is formed integrally with node portion NP1, and the tip side of each of holding members 82b and 82c supports square flange portion 82e extending in the direction perpendicular to the holding member. For further details, both holding members 82b and 82c support node portion NP1 of the vibration body main part 82a at the position of side surfaces facing each other in the X direction, and an end face of each flange portion 82e provided on the tip side of each of both holding members 82b and 82c is firmly fixed on case member 86 to be in contact with an inner surface of case member 86.

As stated above, vibration body for cutting 82 supported in case member 86 is vibrated by axial direction oscillator 83 to be mentioned later, to be in the state of resonance where the standing wave causing displacement locally in the Z direction is formed. Further, the vibration body for cutting 82 is vibrated also by bending oscillator 84, to be in the state of resonance where the standing wave causing displacement locally in the Y axis direction is formed. In this case, node portion NP1 fixed with the root side of holding members 82b and 82c is serving as a node common to axial vibration and bending vibration for the vibration body for cutting 82, which can prevent axial vibration and bending vibration from being disturbed by holding members 82b and 82c.

In the meantime, in vibration body for cutting 82, the holding members 82b and 82c, flange portion 82e and vibration body main part 82a are formed integrally. In other words, the vibration body for cutting 82 is formed integrally on a jointless basis. The vibration body for cutting 82 is formed by cutting a block of material, namely, by cutting bar-shaped material. Owing to this, it is possible to make the vibration body for cutting 82 to vibrate under the desired state, whereby, its strength can be enhanced sufficiently, and its rigidity for holding can be enhanced extremely. The vibration body for cutting 82 can also be formed integrally through molding. The vibration body for cutting 82 can further be one wherein the root side of each of holding members 82b and 82c is fixed to the side surface of vibration body main part 82a through welding.

Axial direction oscillator 83 is a vibration source, which is formed by piezoelectric element (PZT) or super-magnetostrictor, and is connected to the end surface on the root side of vibration body for cutting 82, and it is connected to an oscillator driving device (to be described later) through unillustrated connectors and cables. The axial direction oscillator 83 gives longitudinal waves in the Z direction to the vibration body for cutting 82 by acting based on drive signals coming from the oscillator driving device and by conducting expansion and contraction vibration at high frequency.

Bending oscillator 84 is a vibration source which is formed by piezoelectric element and super-magnetostrictor, and is connected to the side surface on the root side of vibration body for cutting 82, and it is connected to an oscillator driving device (to be described later) through unillustrated connectors and cables. The bending oscillator 84 operates based on drive signals coming from the oscillator driving device, and gives transverse waves, namely, bending vibrations in the Y direction or in the YZ plane in the illustrated example to the vibration body for cutting 82 by vibrating at high frequency.

Counterbalance 85 is fixed to be opposite to vibration body for cutting 82 with respect to axial direction oscillator 83. The counterbalance 85 is a vibration body for cutting that is formed integrally with vibration body for cutting 82 by the same material as that of the vibration body for cutting 82, and specific materials used suitably for the counterbalance 85 include low linear expansion materials such as Invar material, super-Invar material and stainless Invar material. Further, as the material of the vibration body for cutting 82, cemented carbide, iron, quenched steel, stainless steel, aluminium can be used for a use that does not need processing precision.

The counterbalance 85 is equipped with columnar vibration body main part 85a fixed on one end of the axial direction oscillator 83 on a coaxial basis, holding members 85b and 85c supporting node portion NP2 of vibration body main part 85a and flange portion 85e formed on the tip side at each of holding members 85b and 85c. Though each of the two holding members 85b and 85c extending in ±X directions from a side wall of the vibration body main part 85a has a columnar external form in the illustration, it is possible to replace them with those having an external form such as, for example, a square pole, other polyhedral poles or an elliptic cylinder. The root side of each of holding members 85b and 85c is formed integrally with node portion NP2, and the tip side of each of holding members 85b and 85c supports square flange portion 85e extending in the direction perpendicular to the holding member. In other words, both holding members 85b and 85c support node portion NP2 of the vibration body main part 85 at the position of side surfaces facing each other in the X direction, and an end surface of each flange portion 85e provided on the tip side of each of both holding members 85b and 85c is firmly fixed by bolt screw 91 on case member 86 to be in contact with an inner surface of case member 86.

As mentioned above, counterbalance 85 supported together with vibration body for cutting 82 in the case member 86 is vibrated by axial oscillator 83 to result in the state of resonance wherein a standing wave causing displacement locally in the Z direction is formed. In this case, node portion NP2 that has fixed the root sides of the holding members 85b and 85c serves as a node that is common for axial vibration and bending vibration for counterbalance 85, which can prevent that axial vibration and bending vibration are interfered by the holding members 85b and 85c.

In the meantime, in counterbalance 85, the holding members 85b and 85c, flange portion 85e and vibration body main part 85a are formed integrally. In other words, the counterbalance 85 is formed integrally on a jointless basis, in the same way as in vibration body for cutting 82. The counterbalance 85 is formed by cutting a block of material, namely, by cutting bar-shaped material. Owing to this, it is possible to make the counterbalance 85 to vibrate under the desired state, whereby, its strength can be enhanced sufficiently, and its rigidity for holding can be enhanced extremely. The counterbalance 85 can also be formed integrally through molding. The counterbalance 85 can further be one wherein the root side of each of holding members 85b and 85c is fixed to the side surface of vibration body main part 85a through welding.

The case member 86 is a portion in which vibration body assembly 120 that is composed of vibration body for cutting 82 and counterbalance 85 is supported and fixed. The case member 86 is one to fix vibration cutting unit 20 on a processing apparatus (which will be described later) that is for driving the vibration cutting unit 20. Therefore, holes TH for fixing to the processing apparatus are formed at appropriate locations on bottom portion 86b of the case member 86. Further, holes TH for fixing flange portions 82e and 85e extending from vibration body for cutting 82 or counterbalance 85 are formed at appropriate locations on a pair of side wall portions 86a which are formed integrally with the bottom portion 86b. Portions on which these holes TH are formed are supporting portions SP for supporting vibration body for cutting 82 and counterbalance 85. Side wall portion 86a and bottom portion 86b of case members 86 can be formed with the same material (preferably, low linear expansion material) as that of, for example, vibration body for cutting 82. The main part wherein side wall portion 86a and bottom portion 86b are united integrally is formed through cutting of, for example, a block of material, namely, bar-shaped material, and it can also be formed integrally through molding, or through welding of plural plate materials.

On an end surface on one side of case member 86, there is fixed airtightly rear end plate 86f, on an end surface on the other side of case member 86, there is fixed airtightly front end plate 86g and on the top of case member 86, there is fixed airtightly top plate 86h. On the rear end plate 86f, there is formed opening H1 connected to air-supply pipe 96, and there is also formed opening H2 which allows a connector and a cable extending from oscillators 83 and 84 to pass through. The air-supply pipe 96 connected to opening H2 is also connected to a gas-supply device (described later) which supplies pressurized dry air established to the desired rate of flow and temperature. On the other hand, on the front end plate 86g, there is formed opening H3 which allows tool portion 21 of vibration cutting unit 20 to pass through.

In the vibration cutting unit 20, vibration body for cutting 82, axial oscillator 83 and counterbalance 85 are jointed and fixed by, for example, brazing, so that axial oscillator 83 can vibrate efficiently.

On center of axle of each of the vibration body for cutting 82, axial oscillator 83, and counterbalance 85, there is formed through hole 95 that passes through them in a way to traverse their joint surfaces, and pressurized dry air coming from air-supply pipe 96 runs through the through hole. In other words, the through hole 95 is a supply path to send out pressurized dry air, and it constitutes a cooling device for cooling vibration cutting unit 20 from its inside, together with an unillustrated gas supply device and air supply pipe 96. A tip portion of the through hole 95 is communicated with a slit-shaped groove into which cutting tool 23 is inserted to be fixed, and pressurized dry air introduced to the through hole 95 can be supplied to the periphery of the cutting tool 23. Further, a tip of the through hole 95 still has a gap even when the cutting tool 23 is fixed, and therefore, pressurized dry air is jetted at high speed from opening 91a that is formed to be adjacent to the cutting tool 23, whereby, a working point at the tip of the cutting tool 23 can be cooled efficiently, and chips adhering to the working point and its periphery can be removed surely by an air current. Meanwhile, a part of pressurized dry air introduced to case member 86 from air-supply pipe 96 cools vibration body assembly 120 from the outside while passing through the periphery of the vibration body assembly 120, to be jetted out to the outside of case member 86 through a gap of opening H3.

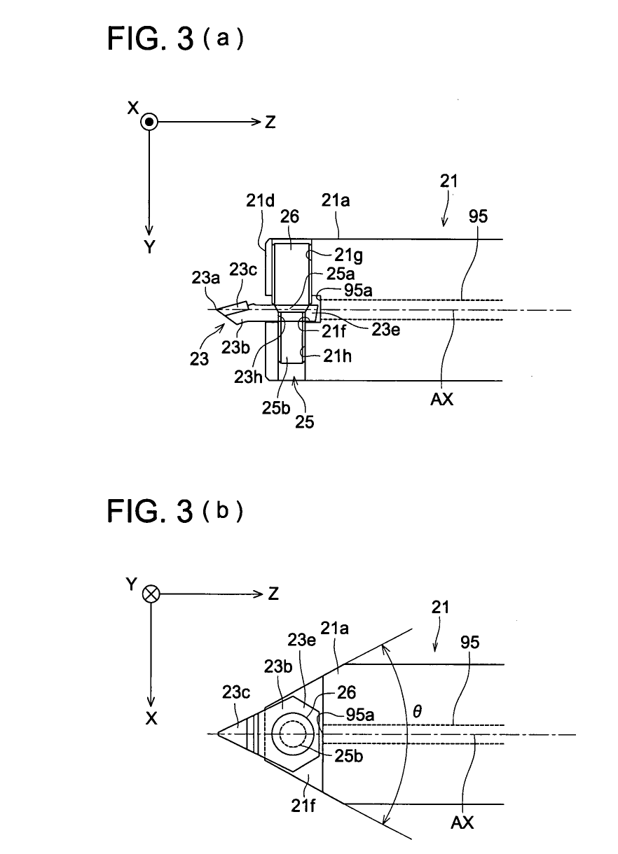

FIGS. 3 (a) and 3 (b) are respectively a side sectional view and a top sectional view of a tip of a tool portion 21 shown in FIG. 1.

As is apparent from FIG. 3, fixing portion 21a provided on the tip of tool portion 21 has a wedge form that is a square form on a side view and a triangular form on a top view. The cutting tool 23 held on fixing portion 21a is equipped with plate-shaped shank 23b whose tip is triangle on the top view and with working tip 23c fixed on a tip portion of the shank 23b. The cutting tool 23 itself is embedded into end face 21d of fixing portion 21a to be fixed, and the tip 23a of the working tip 23c is arranged on an extension of tool axis AX. Further, the working tip 23c and the shank 23b that supports the working tip 23c are arranged inside a wedge-shaped space having open angle θ formed by extension lines of wedge side faces (right and left side faces) of fixing portion 21a. In this case, the open angle θ of the fixing portion 21a is selected to be within a range, for example, of 20°-90°, and a form of the tip can be changed properly to a half circle or a swordtip following a shape of processing purpose as described in Japanese Patent Application 2005-305555.

Root portion 23e of cutting tool 23, namely, of shank 23b is inserted to be fit in slit-shaped groove 21f having a rectangular section engraved in XZ plane along tool axis AX from end face 21d of fixing portion 21a, and it is fixed firmly on the fixing portion 21a by two fixing screws 25 and 26 made of the same material as that of tool portion 21, on a detachable basis. In concrete terms, fixing screws 25 and 26 are successively screwed respectively into fixing holes 21g and 21h passing through upper and lower side surfaces of the fixing portion 21a, for the aforesaid fixing. These fixing holes 21g and 21h are extended in the Y axis direction, and the tightening direction for each of them is perpendicular to the tool axis AX. Both fixing holes 21g and 21h are different each other in terms of their inside diameters, and an inside diameter of the fixing hole 21g is greater than that of the fixing hole 21h. Both fixing holes 21g and 21h are filled respectively with both fixing screws 25 and 26 through screwing. In other words, an arrangement is made so that a deep recessed portion may not be left or a high convex portion may not be formed on positions of the fixing holes 21g and 21h.

The fixing screw 25 on one side to be screwed in the fixing hole 21h is a joining member for fixing the cutting tool 23, and it is a TORX screw including male screw portion 25b and head portion 25a. When the head portion 25a of the male screw portion 25b is screwed by an appropriate tool under the condition that the male screw portion 25b is inserted in the fixing hole 21g through a washer not illustrated, the male screw portion 25b passes through opening 23h formed at root portion 23e and is engaged with a female screw on an inner surface of fixing hole 21h formed in the inner part of the fixing hole 21g. In this case, the root portion 23e of cutting tool 23 is interposed between head portion 25a, a washer and an inner surface of slit-shaped groove 21f to be tightened, and the root portion 23e is fixed from the primary surface side, whereby, separation of the cutting tool 23 is prevented and fixing of the cutting tool 23 is secured.

Fixing screw 26 on the other side to be screwed into fixing hole 21g is the so-called worm screw, and it functions as a setting member for preventing the fixing screw 25 from coming off. When an upper end of this fixing screw 26 is screwed by an appropriate tool while its lower end is positioned at the fixing hole 21g, the fixing screw 26 is engaged with a female screw on the inner surface of the fixing hole 21g and it is screwed in the fixing hole 21g to fill the inside thereof. The fixing screw 26 thus screwed-in tightens the fixing screw 25 at the upper end, and the fixing screw 25 is prevented from loosening. In the foregoing, fixing holes 21g and 21h and fixing screws 25 and 26 serve as a fixing device to fix cutting tool 23 on tool portion 21.

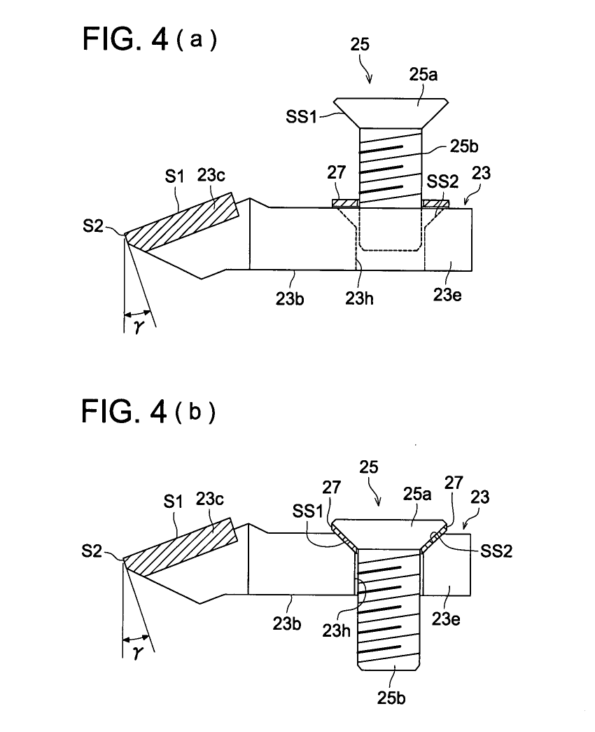

FIGS. 4(a) and 4(b) are an enlarged side view and an enlarged cross sectional view for describing the structure and fixing method of a cutting tool 23.

In the cutting tool 23, a shank 23b is a support member made of ceramics and although it is light but is hardly bent. Further, a processing tip 23c is a tip made of a diamond having a cutting edge and is fixed to the tip of the shank 23b by the active metal method and brazing. A root portion 23e of the shank 23b is fastened and fixed so as to be pressed to the bottom surface of a slit-shaped groove 21f formed in a fixing portion 21a shown in FIG. 3 by a fixing screw 25 and a washer 27. In this case, the washer 27 is a ring-shaped member transformable as a cushioning member and prevents the fastening stress by the fixing screw 25 from locally concentrating. The washer 27, before fastened by the fixing screw 25, as shown in FIG. 4(a), is a ring-shaped member composed of a flat circular plate with the center thereof hollowed out. However, after fastened by the fixing screw 25, as shown in FIG. 4(b), the washer 27 is a three-dimensional member corresponding to the side surface of a cone portion. Namely, the washer 27 is held between a seating face SS1 which is a pressing portion formed on the bottom surface of a head portion 25a of the fixing screw 25 and a seating face SS2 which is a pressed portion formed around the upper portion of an opening 23h and is transformed so as to be suited to the seating faces SS1 and SS2. The washer 72 can be in the shape of the side surface of cone portion in advance. Further, the root portion 23e of the shank 23b and the bottom surface of the slit-shaped groove 21f have smooth surfaces and are assembled in the closely adhered state free of foreign substances.

Further, in the processing tip 23c of the cutting tool 23, a cutting face S1 at the tip has an open angle θ of, for example, about 60° (refer to FIG. 3(b)) and is an R cutting tool having a tip in a circular arc shape. Here, the cutting face S1 is referred to as a surface contributing to cutting of a material to be cut by the cutting tool 23. The normal line of the cutting face S1 is parallel with the longitudinal bending vibration plane parallel with the YZ plane of the cutting tool 23 and the vibration cutting using precisely the longitudinal bending vibration without wasting is made possible. Further, the radius of the circular arc of the tip of the cutting face S1 formed at the tip of the processing tip 23c is, for example, about 0.8 mm and a clearance angle γ of clearance surface S2 is, for example, about 5°. Here, the clearance angle γ is referred to as an angle formed by the tangent at the cutting-in point of the clearance surface S2 or the extension line thereof and the tangent of the processing surface at the cutting point. The shape of the processing tip 23c described above is an example illustration and as described in Japanese Patent Application 2005-305555, a tip having a tip shape such as a sharper swordtip cutting tool or a half circle cutting tool can be used.

As a material of the shank 23b, from the viewpoint of realization of light weight and securing of rigidity, for example, ceramic materials such as alumina, silicon nitride, silicon carbide, and zirconia are cited as candidates, and the vibration attenuation can be reduced. However, for example, zirconia has density of 6 and is lighter than high-speed steel by 25%, so that it is effective on realization of vibration cutting at a high frequency. However, from the viewpoint of weight, ceramics having a weight of about ⅔ thereof such as alumina and silicon nitride are more preferable. Furthermore, the shank 23b, from the viewpoint of reduction in heat transformation, is desirably formed with a material of a linear expansion coefficient of 5×10⁻⁶ or less. As a ceramic material corresponding to it, there are silicon nitride and silicon carbide available. Further, the linear expansion coefficient used for the above explanation indicates the average linear expansion coefficient, for example, at 0° C. to 50° C. where the shank 23b is used actually. Furthermore, the shank 23b is formed by a ceramic material which is a sintered material and has hardness of HV1000 or higher and when it is formed by silicon carbide, the hardness thereof reaches HV2200.

As a concrete material of the shank 23b, for example, a material containing silicon nitride as a main component, that is, a material containing silicon nitride of 50 wt % or more is desirable. Concretely, commercially available silicon nitride ceramics and sialon correspond to it. These materials have density of about 3.3 and a Young's modulus of elasticity of 270 to 300 GPa, so that compared with high-speed steel which is a conventional shank material, the weight is ½ or less and the Young's modulus of elasticity is 1.3 times or more. Therefore, when the shank 23b is formed with a material containing silicon nitride as a main component, vibration at a high frequency of 1 kHz or higher can be realized easily and it is advantageous for realization of highly efficient vibration cutting work free of bending and chattering.

The processing tip 23c is formed by a material such as not only a diamond but also boron nitride (BN) according to a cutting object. When fixing the cutting tip 23c to the shank 23b made of a ceramic material, the joining method called an active metal method is used. When using the active metal method, compared with silver brazing, the processing tip 23 can be joined more strongly to the shank 23b. By this method, at the location of the shank 23b to be joined, a thin plate of a brazing material including a metal such as Ag, Cu, or Ti which are active at high temperature is sandwiched and is left in a vacuum atmosphere or an inactive gas atmosphere at about 1000° C. for several hours, thus the activated metal is diffused and bonded to the ceramic material, thus stronger bonding than ordinary brazing depending on only wettability is obtained. The active metal method is not limited to the method using the thin plate of the brazing material and it is possible to adhere a brazing material onto the joining surface by sputtering or deposition or coat paste such as minute particles or amalgam.

The fixing screw 25 is a threaded member formed by cutting or component rolling of a metallic material. To the fixing screw 25, from the viewpoint of securing of the processability of a male screw portion 25b, a material of excessively high hardness is not suited. Furthermore, from the viewpoint of securing of the fastening strength of the fixing screw 25, for the fixing screw 25, it is necessary to increase the fracture toughness value and ensure a Young's modulus of elasticity of a fixed value or higher. Further, from the viewpoint of preventing the shank 23b from being damaged, the fixing screw 25 desirably has hardness of a certain degree or lower (for example, lower than the hardness of the shank 23b). Namely, the fixing screw 25 is required to have hardness not excessively high. Further, from the viewpoint of vibration, it is desirable to use the fixing screw 25 of a material having hardness equivalent to or lower than that of the support body and having a vibration characteristic equivalent to or more easy to vibrate than that of a vibration body for vibration cutting 82. By fastening by this fixing screw 25, the loss of vibration transfer by the fixing screw 25 is reduced and the vibration energy can be transferred to the vibration body for cutting 82 and the tip portion of the cutting tool 23. As a material of the fixing screw 25, a highly strong metallic material such as high-speed steel is used preferably.

The washer 27, from the viewpoint that it is sandwiched and transformed between the shank 23b and the fixing screw 25, is required to have hardness lower than that of the shank 23b and fixing screw 25. Concretely, the Vickers hardness of the washer 27 is assumed to be HV300 or lower. Furthermore, the washer 27 is desirably formed by a transformable material not damaged during transformation, for example, a soft metal. By doing this, the washer 27 is sandwiched and easily transformed between the shank 23b and the fixing screw 25 and the shank 23b can be prevented from local concentration of the stress. As a concrete material of the washer 27, any of the metallic materials of Al, Cu, Pb, Ti, Sn, Zn, Ag, Au, and Ni can be used and an alloy of these metallic materials can be also used. Further, the thickness of the washer 27 is desirably 0.05 mm to 0.5 mm.

Next, a concrete embodiment of the cutting tool 23 and tool portion 21 will be described. Aluminum is used for the washer 27 which is a ring-shaped cushioning member, silicon nitride for the shank 23b, chrome molybdenum steel for the fixing screw 25, and high-speed steel for the support body which is the vibration body for cutting 82 or a fixing portion 21a. As Vickers hardness, aluminum has HV170, silicon nitride has HV1400, chrome molybdenum steel has HV350, and high-speed steel has HV640. The thickness of the washer 27 is 0.3 mm. The shank 23b is fastened to the support body using the fixing screw 25 and washer 27.

Further, when the washer 27 is not used like a conventional method, the silicon nitride shank having a small fracture toughness value is directly fixed by a fixing screw of chrome molybdenum steel. Then, although the hardness of silicon nitride is high overwhelmingly, the fracture toughness value is small, so that due to the local stress concentration at contact points caused by irregularities of the seating face where the fixing screw and shank make contact with each other, the shank is frequently damaged.

Therefore, as in this embodiment, when aluminum with hardness of HV170 is arranged between the seating faces SS1 and SS2 as a washer 27, the irregularities of the seating faces SS1 and SS2 are reduced due to transformation of the washer and the local stress concentration is prevented from occurring. As a result, the shank 23b can be fastened by torque 200 cN·m which is 2.0 times of the conventional one and can be strongly fixed to the support body which is the vibration body for cutting 82.

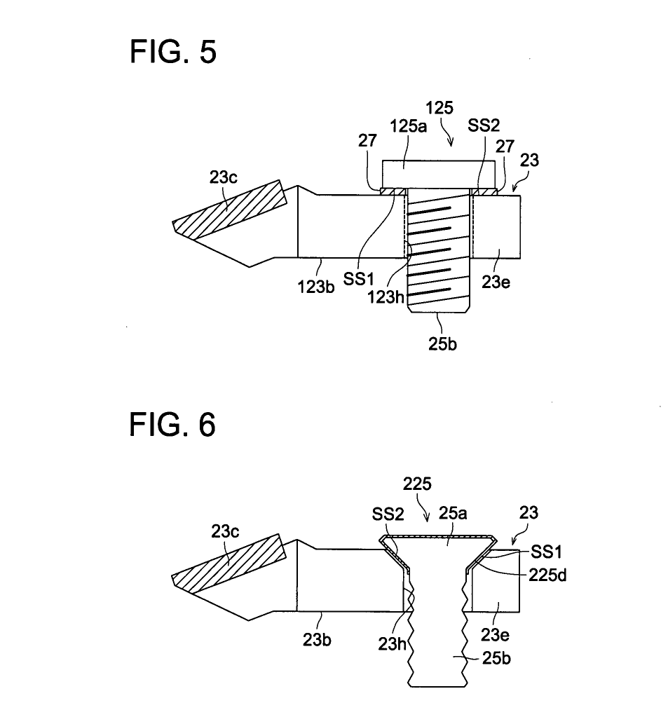

FIG. 5 is an enlarged side view for describing a variation example of the cutting tool 23 shown in FIG. 4 and the fixing method therefor. In the cutting tool 23, the seating face SS2 formed around an opening 123h formed in the root portion 23e of a shank 123b is a flat plane and in correspondence with it, a fixing screw 125 is a flat head screw instead of a countersunk screw. Namely, the seating face SS1 formed on the bottom surface of a head portion 125a of the fixing screw 125 is also a flat plane. In this case, the washer 27 used to fasten the fixing screw 125 is sandwiched between the seating faces SS1 and SS2, and from the beginning, it has a shape corresponding to the shape of the seating faces SS1 and SS2. However, when the fixing screw 125 is fastened, the surface of the washer 27 made of a mild metal is transformed and the seating faces SS1 and SS2 are closely adhered to the top and bottom of the washer 27. By doing this, the washer 27 is sandwiched between the fixing screw 125 and the shank 123b and functions as a cushioning member, thus the fastening stress by the fixing screw 125 can be prevented from locally concentrating.

FIG. 6 is an enlarged cross sectional view for describing another variation example of the cutting tool 23 shown in FIG. 4 and the fixing method therefor. The cutting tool 23 is fixed to the fixing portion 21a shown in FIG. 3 by a fixing screw 225 coated with a soft metal. Namely, the fixing screw 225 is added with a layer 225d obtained by coating a soft metal on the surface of the head portion 25a which is a main part. In this case, the washer 27 shown in FIG. 4 or others is not necessary and the coating layer 225d is sandwiched between the seating face SS1 which is the bottom surface of the head portion 25a and the seating face SS2 which is the periphery of the opening 23h. Namely, by fastening the fixing screw 225, the coating layer 225d is closely adhered to the seating face SS2, thereby prevents local stress concentration.

Further, to form the layer 225 obtained by coating a soft metal, not only the PVD such as electrolytic plating, electroless plating, sputtering, and deposition but also the film forming technology such as the heat CVD and plasma CVD can be used.

Further, the coating layer 225d can be formed not only on the fixing screw 225 but also on the shank 23b. Namely, it is possible to coat the opening 23h and its periphery instead of coating the fixing screw 225. In such a variation example, the washer does not need always to function as a cushioning member and it can be omitted. In these cases, the plated layer 225d functions as a cushioning member arranged between the shank 23b and the fastening member such as the fixing screw 225.

However, when the coating layer 225d is formed on the shank 23b and the fixing screw 225 is fastened repeatedly, the coating layer 225d is damaged and stripped, so that the shank 23b must be coated again. In this case, so as to prevent the processing tip 23c from being touched and the cutting edge of the tip from being damaged, it is necessary to work with the greatest care. Further, depending on the coating method, there are possibilities that the processing tip 23c not to be coated may be coated. Therefore, it is desirable to coat the fixing screw 25.

Next, a concrete embodiment of the cutting tool 23 and tool portion 21 will be described. Silicon nitride is used for the shank 23b, chrome molybdenum steel for the fixing screw 25, and high-speed steel for the support body which is the vibration body for cutting 82 or the fixing portion 21a. Further, the seating face SS1 of the fixing screw 25 is coated with copper with a thickness of 200 μm by electroless plating. As Vickers hardness, silicon nitride has HV1400, chrome molybdenum steel HV350, high-speed steel HV640, and the electroless copper plated layer HV50. In this case, copper which is a soft metal for a cushioning member is coated on the seating face SS1 of the fixing screw, so that the washer 27 is not necessary. Similarly to the aforementioned embodiment, when the shank 23b was fastened to the support body which was the vibration body for cutting 82, compared with the similar conventional one, the shank 23b could be fastened by torque 200 cN·m which is 2.0 times of the conventional one and could be strongly fixed to the vibration body for cutting 82. Thereafter, when the fixing screw 25 was loosened and the electroless copper plated surface was observed, scratches caused by mutual rubbing of the seating faces were seen. Furthermore, when the fixing screw 25 was used and the shank 23b was mounted and demounted repeatedly. At the fifth time, the shank 23b was damaged at torque of 130 cN·m. When the seating face SS1 of the fixing screw 25 was observed, a part of the coating layer was stripped and the surface of the fixing screw which was the substrate was seen. Therefore, in actual use, for safety, when the same fixing screw 25 has been used three times, it is exchanged for a new fixing screw.

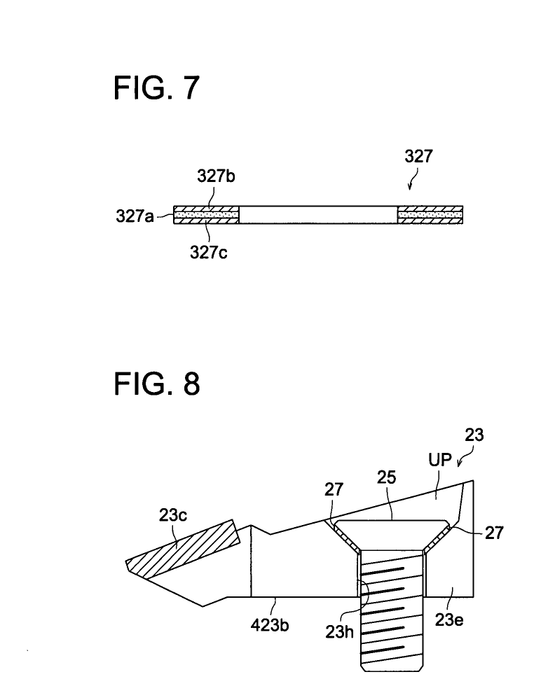

FIG. 7 is an enlarged cross sectional view for describing still another variation example of the cutting tool 23 shown in FIG. 4 and the fixing method therefor. In this case, a washer 327 has a multilayer structure. The washer 327 has a body layer 327a and surface layers 327b and 327c. Here, the surface layers 327b and 327c are formed of a soft metal, however the body layer 327a can be formed of a metallic material harder than it. The washer 327 shown in FIG. 7 is sandwiched between the root portion 23e of the shank 23b shown in FIG. 4(b) and the head portion 25a, thereby is closely adhered to the seating faces SS1 and SS2. By doing this, the washer 327 functions as a cushioning member and the fastening stress by the fixing screw 25 can be prevented from locally concentrating. Further, as mentioned above, the washer 327 is divided into the body material and surface material such as the body layer 327a and the surface layers 327b and 327c. When the surface material functions as a cushioning member, the portion composing the surface material indicates the hardness of the cushioning member.

FIG. 8 is an enlarged cross sectional view for describing a further variation example of the cutting tool 23 shown in FIG. 4 and the fixing method therefor. In this case, the thickness of the root portion 23e of a shank 423b is changed and the diameter of an upper part UP of the opening 23h is increased. In the example drawn, the thickness of the shank 423b is decreased toward the tip, however even if the thickness of the shank 423b is increased toward the tip, the shank 423b can be fixed similarly by the fixing screw 25 and washer 27.

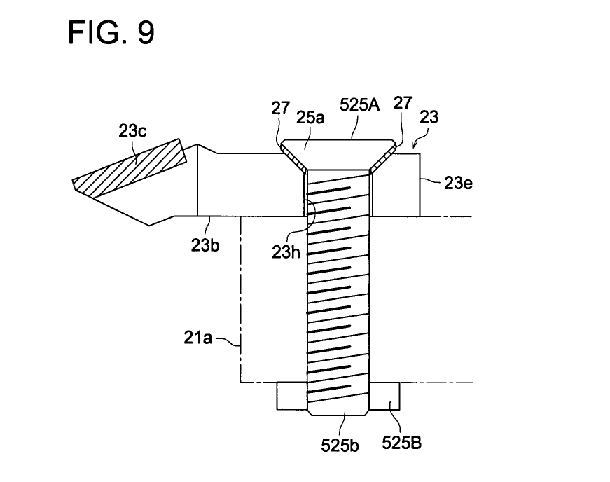

FIG. 9 is an enlarged cross sectional view for describing a still further variation example of the cutting tool 23 shown in FIG. 4 and the fixing method therefor. In this case, a fixing screw 525A is not fastened and fixed directly to the fixing portion 21a but the root portion 23e of the shank 23b is fastened by the fixing screw 525A and a fixing nut 525B and is fixed to the fixing portion 21a. In this case, the fixing screw 525A and fixing nut 525B function as a fastening member, and furthermore, the washer 27 is sandwiched between the fixing screw 525A and the root portion 23e of the shank 23b and functions as a cushioning member, thus the fastening stress by the fixing screw 125 can be prevented from locally concentrating.

### Second Embodiment

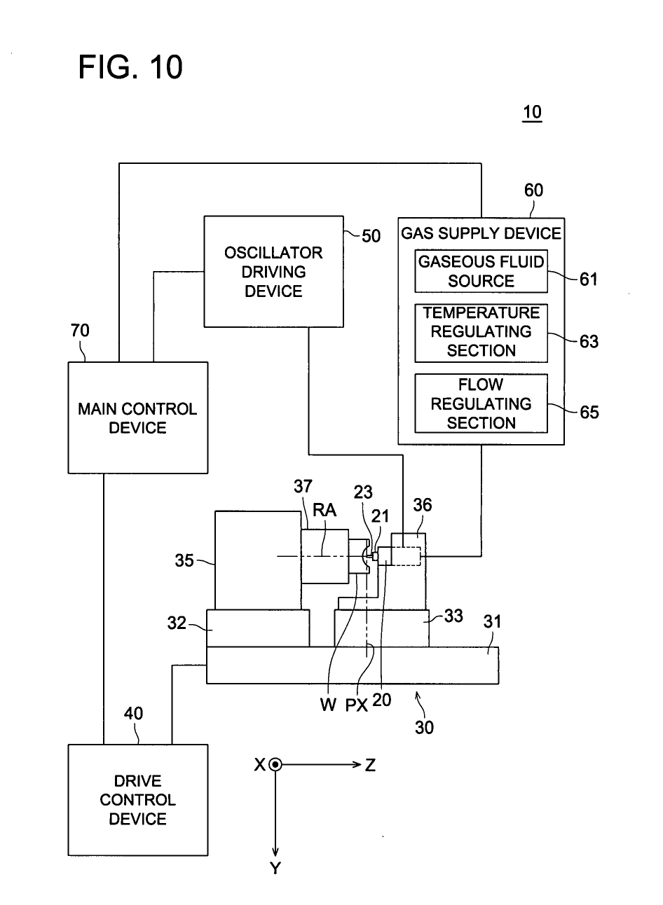

A processing apparatus relating to the second embodiment of the invention will be described as follows, referring to the drawings. FIG. 10 is a block diagram illustrating conceptually the structure of a processing apparatus of a vibration cutting type that processes an optical surface of a molding die which molds an optical element such as a lens.

As shown in FIG. 10, processing apparatus 10 is equipped with vibration cutting unit 20 for cutting work W representing an object to be processed, NC drive mechanism 30 that supports the vibration cutting unit 20 for the work W, drive control device 40 that controls operations of the NC drive mechanism 30, oscillator driving device 50 that gives desired vibrations to the vibration cutting unit 20, gas supply device 60 that supplies gas for cooling to the vibration cutting unit 20 and main control device 70 that controls operations of the total apparatus on a general control basis.

The vibration cutting unit 20 is a vibration cutting tool wherein cutting tool 23 is embedded in the tip of tool portion 21 extending in the Z direction, and high frequency vibrations of this cutting tool 23 cut the work W efficiently. The vibration cutting unit 20 has the structure described in the first embodiment.

The NC drive mechanism 30 is a driving device having the structure wherein first stage 32 and second stage 33 are placed on pedestal 31. The first stage 32 supports first movable portion 35 which supports the work W indirectly through chuck 37. The first stage 32 can move the work W to the desired position at desired speed in, for example, the Z direction. Further, the first movable portion 35 can rotates the work W around horizontal axis of rotation RA at the desired speed. On the other hand, the second stage 33 supports second movable portion 36 which supports the vibration cutting unit 20. The second stage 33 can support the second movable portion 36 and the vibration cutting unit 20, and can move these to the desired positions along X axis direction or Y axis direction, at the desired speed. Further, the second movable portion 36 can rotate the vibration cutting unit 20 around vertical pivot axis PX that is in parallel with Y axis by a desired amount of angle at the desired speed. In particular, it is possible to rotate the vibration cutting unit 20 around its tip point by a desired angle by arranging the tip point of the vibration cutting unit 20 on the vertical pivot axis PX after adjusting properly a fixing position and angle of the vibration cutting unit 20 for the second movable portion 36.

Incidentally, in the aforesaid NC drive mechanism 30, the first stage 32 and the first movable portion 35 constitute a work driving portion that drives the work W, while, the second stage 33 and the second movable portion 36 constitute a tool driving portion that drives the vibration cutting unit 20.

The drive control device 40 is one to make highly accurate numerical control possible, and it operates properly the first stage 32, the second stage 33, the first movable portion 35 and the second movable portion 36 to the aimed states, by driving a motor and a position sensor housed in NC drive mechanism 30 under the control of the main control device 70. For example, while moving (feeding operation), at a low speed, a processing point of the tip of cutting tool 23 provided on a tip of tool portion 21 of vibration cutting unit 20, relatively for work W, along the prescribed locus established in a plane parallel to XZ plane, by the first stage 32 and the second stage 33, it is possible to rotate the work W at high speed around horizontal axis of rotation RA by the first movable portion 35. As a result, NC drive mechanism 30 can be utilized as a highly precise lathe under the control by drive control device 40. In this case, the tip of cutting tool 23 can be rotated properly around vertical pivot axis PX, with a processing point corresponding to the tip of cutting tool 23 serving as a center by the second movable portion 36, thus, the tip of cutting tool 23 can be set to the desired posture (inclination) for the point of work W to be processed.

Oscillator drive device 50 is one to supply electric power to a vibration source built in vibration cutting unit 20, and it can vibrate the tip of tool portion 21 at desired frequency and desired amplitude under the control of main control device 70, with a built-in oscillation circuit and a PLL circuit. Incidentally, a tip of the tool portion 21 is capable of conducting a bending vibration in the direction perpendicular to the axis (namely, tool axis AX extending in the direction of a depth of cut), and a vibration in the axial direction, and its two-dimensional vibration and three-dimensional vibration make it possible to conduct minute and efficient processing in which the tip of the tool portion 21, that is, the cutting tool 23 faces a surface of the work W.

Gas supply device 60 is one to cool the vibration cutting unit 20, and it is equipped with gaseous fluid source 61 that supplies pressurized dry air, temperature adjusting portion 63 serving as a temperature adjusting device that allows the passage of pressurized dry air coming from the gaseous fluid source 61 to adjust its temperature and flow rate adjusting portion 65 serving as a flow rate adjusting device that adjusts the flow rate of pressurized dry air having passed through the temperature adjusting portion 63. In this case, the gaseous fluid source 61 feeds air into a drying machine employing, for example, a thermal process or a dessicator to dry the air, and pressure of the dried air is enhanced by a compressor to the desired pressure. Further, temperature adjusting portion 63 that is not illustrated has, for example, flow channels for circulating coolants to peripheries and temperature sensors provided on the half way of the flow channels, and it can adjust pressurized dry air that has passed through the flow channel to the desired temperature by adjusting temperature and an amount of supply of the coolant. In addition, the flow rate adjusting portion 65 has, for example, a valve or a flow controller (not shown), and it can adjust a flow rate in the case of supplying the temperature-adjusted pressurized dry air to vibration cutting unit 20.

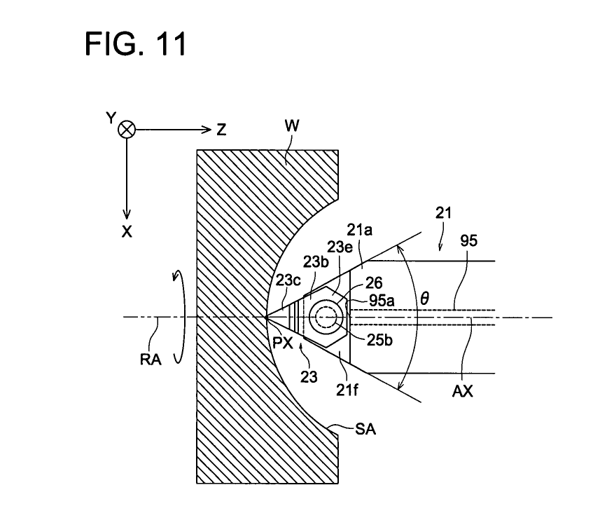

FIG. 11 is an enlarged top view for illustrating how work W is processed by processing apparatus 10 shown in FIG. 10. Fixing portion 21a of tool portion 21 vibrates at high speed on YZ plane, for example, as described already. Further, the fixing portion 21a is moved gradually on XZ plane for work W representing an object to be processed by NC drive mechanism 30 shown in FIG. 10, while drawing the prescribed locus. That is, feeding operations for the tool portion 21 are conducted. Further, the work W representing an object to be processed is rotated at the constant speed around rotation axis RA that is in parallel with Z axis, by NC drive mechanism 30 shown in FIG. 10 (see FIG. 10). Owing to this, lathing processing for work W is made possible, and it is possible to form, for example, surface to be processed SA (for example, stepped surface such as phase element surface in addition to curved surface such as concavoconvex spherical surface and aspheric surface) that is rotation-symmetrical around rotation axis RA for the work W. In this case, vibration surface (elliptic orbit EO) of the tip of cutting tool 23 is made to be perpendicular substantially to the surface to be processed SA which is to be formed on the work W, by rotating the tip of cutting tool 23 of tool portion 21 around pivot axis PX that is in parallel with Y axis direction by the use of second stage 33. Owing to this, a processing point on the cutting edge of cutting tool 23 can be maintained at one point substantially during processing, whereby, efficient transmission of vibration to the processing point and highly accurate vibration cutting that depends on no cutting edge form can be realized, thus, processing accuracy for surface SA to be processed can be enhanced, and surface SA to be processed can be made to be more smooth. Further, since pressurized dry air is jetted at high speed toward the tip of cutting tool 23 from opening 95a on the tip of tool portion 21 in the course of processing of work W, it is possible not only to cool cutting tool 23 and surface SA to be processed efficiently but also to make temperatures of cutting tool 23 and of surface SA to be processed to be within a certain range by temperature and flow rate of pressurized dry air. Since this pressurized dry air is introduced via through hole 95 that passes through a center of axle of tool portion 21, to flow through insides of vibration body for cutting 82, axial oscillator 83 and counterbalance 85, temperatures of vibration body for cutting 82 and others can be adjusted by temperature and flow rate of the pressurized dry air. Temperatures of the vibration body for cutting 82 can be stabilized by adjusting the temperature of the pressurized dry air as stated above, and a surface subjected to cutting work having high accuracy and high reproducibility can be obtained.

### Third Embodiment

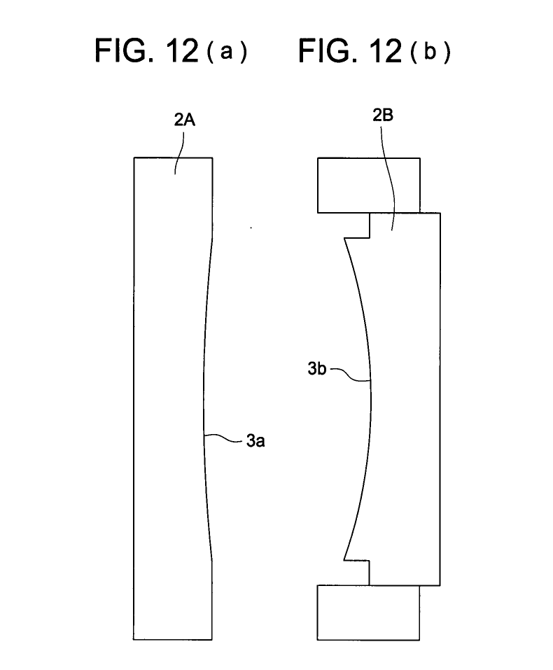

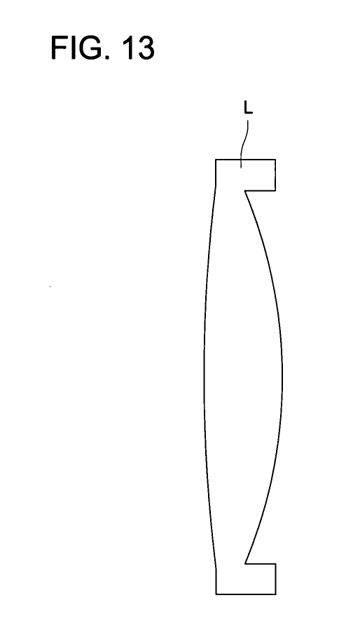

A molding die relating to the third embodiment of the invention will be described as follows. FIG. 12 is a diagram illustrating an molding die (molding die for optical element) prepared by using vibration cutting unit 20 in the first embodiment, in which FIG. 12 (a) is a side sectional view of a fixed mold that is first mold 2A, and FIG. 12 (b) is a side sectional view of a movable mold that is second mold 2B. Optical surfaces 3a and 3b respectively of both molds 2A and 2B are those subjected to finishing processing conducted by processing apparatuses 10 shown in FIG. 10 or others. In other words, a material (material is, for example, cemented carbide) for each of both molds 2A and 2B is fixed on chuck 37 as work W, and oscillator driving device 50 is operated to vibrate cutting tool 23 at high speed while forming standing waves on vibration cutting unit 20. Simultaneously with this, drive control device 40 is operated appropriately to move optionally the tip of tool portion 21 of vibration cutting unit 20 for work W on a three-dimensional basis. Due to this, transfer optical surfaces 3a and 3b respectively of both molds 2A and 2B can be made to be a stepped surface, a phase structure surface and a diffractive structure surface without being limited to a spherical surface and an aspheric surface.

FIG. 13 is a sectional view of lens L press-molded by the use of mold 2A shown in FIG. 12 (a) and mold 2B shown in FIG. 12 (b). When optical surfaces 3a and 3b respectively of molds 2A and 2B have a stepped surface, a phase structure surface and a diffractive structure surface, the formed optical surfaces of lens L also have a stepped surface, a phase structure surface and a diffractive structure surface though not illustrated. Further, a material of lens L can be glass without being limited to plastic. Incidentally, lens L can also be made directly by processing apparatus 10 in the second embodiment.

Hereinafter, a concrete processing embodiment using the vibration cutting unit 20 having the cutting tool 23 shown in FIG. 4 and the processing apparatus 10 shown in FIG. 10 with the vibration cutting unit 20 incorporated will be described.

The cutting tool 23 using the shank 23b made of silicon nitride equipped with the processing tip 23c made of a single-crystal diamond was fastened to the fixing portion 21a at the tip of the tool portion 21 of the vibration cutting unit 20 of an elliptical vibration type, as shown in FIG. 4, using the fixing screw 25 and aluminum washer 27. The dimensions of the washer 27 was an inside diameter of 4.3 mm, an outside diameter of 9.0 mm, and a thickness of 0.4 mm.

Further, conventionally, when fixing the shank 23b made of silicon nitride, the washer 27 was not used, so that when it was intended to fasten the cutting tool 23 at torque of about 180 cN·m necessary to strongly fix it, the shank 23b was damaged.

Therefore, in this embodiment, when the washer 27 aforementioned is used and the cutting tool 23 is fastened at torque of 180 cN·m, even if the tool is repeatedly mounted and demounted 20 times, the shank 23b is not damaged at all and the cutting tool 23 can be fixed strongly. To verify the influence of existence of the washer 27 on the processing surface, the condition of the processing surface was compared, in the case that the cutting tool 23 was fixed without using the washer 27 as conventionally, and the case that the cutting tool 23 was fixed by using the washer 27 of this embodiment. The results will be described later.

In the actual processing, vibration cutting was executed using the processing apparatus 10 shown in FIG. 10, that is, a superprecision lathe and a die was manufactured. As shown in FIG. 10, on a pedestal 31, a first stage 32 for driving a workpiece W in the Z-axial direction and a second stage 33 for driving the vibration cutting unit 20 in the X-axial direction are mounted. On the first stage 32 for the axis Z, a first movable portion 35 for driving the workpiece W to rotate is mounted and on the second stage 33 for the axis X, a second movable portion 36 for moving the vibration cutting unit 20 is mounted. The tip of the tool portion 21 of the vibration cutting unit 20 is fixed onto a pivot axis PX.

The processing chip 23a of cutting tool 23 used for cutting is an R cutting tool wherein an angle of opening of cutting face S1 on the tip is 60° and the tip is formed to be in a circular arc form. A radius of the circular arc on the tip on cutting face S1 of a cutting edge is 0.8 mm, clearance angle γ of clearance surface is 10° and an angle formed by cutting face S1 at a point of cut is −15°. An amount of cut by the processing chip 23a in this case is 2 μm. In the vibration cutting of the present embodiment, the cutting tool 23 vibrates in each of both the axis direction and the bending direction, while, the cutting edge of the processing chip 23a conducts circular motion or elliptic motion. Consequently, cutting was done in a way to scoop up with cutting face S1, and thereby, it was possible to make an amount of cut to be several times as large as that in an ordinary processing which is not vibration cutting, even in the case of ductile mode cutting.

In this embodiment, to compare simply the difference in the processed surface due to the difference in the fixing state of the cutting tool 23, the processing shape was decided as a plane. As a material of the workpiece W, Microalloy F (hardness HV 1850) by Tungaloy Corporation was used.

Firstly, by the conventional method, the cutting tool 23 was fixed without using the washer 27, and elliptical vibration cutting is executed, and the optical surface roughness was measured using the surface roughness measuring instrument HD 3300 by WYKO, Ltd., and average surface roughness of Ra 7.3 nm was obtained. Further, when the workpiece surface after processing was observed by a differential interference microscope, on the processed surface, a cutting edge mark due to chattering of the cutting tool 23 was seen. On the other hand, when the cutting tool 23 was fixed by the aforementioned method of this embodiment and the elliptical vibration cutting was executed, the average surface roughness was improved to Ra 3.4 nm and a satisfactory optical mirror surface (transfer optical surface) was obtained. Further, when the surface of the workpiece W after processing was observed by the differential interference microscope, no chattering markings of the cutting tool 23 were seen on the processing surface. Therefore, it was found that by the conventional tool fixing method, the shank 23b was fixed so as not to be damaged, so that the cutting tool 23 was not fixed strongly, while by use of the method of the present invention, the cutting tool 23 can be fixed strongly and chattering of the processing surface can be eliminated.

Though the invention has been described, referring to the embodiments, the present invention is not limited to the aforesaid embodiments. For example, in the vibration cutting unit 20, the entire form and dimensions of the vibration body for cutting 82 or axial oscillator 83 can be modified suitably according to the use. Further, the form, position, number of holding members 82b and 82c for supporting vibration body for cutting 82 and others can be modified suitably.

Further, when vibration cutting unit 20 is not heated much, supply of pressurized and dried air is not necessary, because dimension changes of the vibration body for cutting 82 do not need to be worried about. Further, in gas supply device 60 shown in FIG. 9, it is possible to use gaseous fluid wherein oil and other lubricant elements other than air are added as misted solvents and particles as well as inert gas such as nitrogen gas.

Further, vibration bodies 82 constituting assembly of vibration body 120 do not need to be single like the above embodiment, and an oscillator exciting the vibration body may also be plural or may be plural pairs.

Although cutting by a lathe has been described mainly in the aforesaid vibration cutting apparatus, vibration cutting unit 20 shown in FIG. 1 and processing apparatus 10 can also be changed for ruling processing.

What is claimed is:

1. A cutting device comprising:
a cutting tool for vibration cutting including
a tip having a cutting edge; and
a shank made of a ceramic for holding the tip;
the cutting device further comprising:
a support body for supporting the shank of the cutting tool and for transmitting vibration to the cutting tool;
a fastening member for fastening to fix the cutting tool to the support body; and
a cushioning member between the shank and a head portion of the fastening member, the cushioning member being formed of a material having lower hardness than hardness of a body material of the shank and having lower hardness than hardness of a body material of the fastening member.

2. The cutting device of claim 1,
wherein the fastening member is a screwing member in form of a mail thread and the cushioning member is a ring member.

3. The cutting device of claim 1,
wherein the cushioning member is previously formed to have a shape corresponding to a shape of a pressing portion of the fastening member.

4. The cutting device of claim 1,
wherein the cushioning member is transformable to have a shape corresponding to a shape of a pressing portion of the fastening member.

5. The cutting device of claim 1,
wherein the cushioning member is formed of a material which includes a soft metal on a surface of the cushioning member.

6. The cutting device of claim 1,
wherein hardness of a body material of the fastening member is lower than hardness of the support body.

7. The cutting device of claim 1,
wherein a soft metal constituting the cushioning member includes at least one element selected from a group consisting of AL, Cu, Pb, Ti, Sn, Zn, Ag, Au and Ni.

8. The cutting device of claim 1,
wherein the cushioning member has Vickers hardness of HV 300 or less.

9. The cutting device of claim 1,
wherein the cushioning member is a coating layer on the head portion or on the shank.

10. The cutting device of claim 1,
wherein the support body constitutes a vibration body main part for transmitting a bending vibration and an axial vibration to the cutting tool.

11. The cutting device of claim 1, further comprising:
a vibration source for vibrating the cutting tool through a vibration body main part by providing vibration to the vibration body main part.

12. A processing apparatus comprising:
the cutting device of claim 1; and
a driving device for moving the cutting device while operating the cutting device.

13. A molding die having a transfer optical surface manufactured by the cutting device of claim 1, for forming an optical surface of an optical element.

14. An optical element manufactured by the cutting device of claim 1.

15. A cutting method,
wherein cutting is conducted by providing vibration to the cutting device of claim 1.
